(19) United States
(12) Patent Application Publication
(10) Pub. No.: US 2007/0072128 A1
(43) Pub. Date: Mar. 29, 2007

(54) Method of manufacturing an integrated circuit to obtain uniform exposure in a photolithographic process

(76) Inventors: Frank Miceli, Orlando, FL (US); Jose Omar Rodriguez, Orlando, FL (US); Andres B. Garcia, Ocoee, FL (US); Charles A. Storey, Orlando, FL (US)

Correspondence Address: HITT GAINES, PC;AGERE SYSTEMS INC., PO BOX 832570, RICHARDSON, TX, 75083, US

(21) Appl. No.: 11/237,569

(22) Filed: Sep. 28, 2005

(51) Int. Cl. G03F 7/20

(52) U.S. Cl. 430/311

(57) ABSTRACT

A method of manufacturing an integrated circuit in which the method comprises exposing a wafer to an energy source defining a focal plane with which a depth of focus is associated and conforming the wafer to substantially correspond with the focal plane.

### FIELD OF THE INVENTION

The present invention relates to the manufacture of semiconductor integrated circuits, and more specifically, to a method for improving element definition in a photolithography process.

### BACKGROUND OF THE INVENTION

Integrated circuit (IC) fabrication involves a process sequence in which patterns are generated in different material layers using, for example, a combination of deposition, lithography, and etching techniques. After the formation of a material layer on a silicon wafer, lithographic and etching techniques are used to transfer a desired pattern into the material, or to process the exposed substrate material. Typically, a radiation-sensitive material, called a resist, is spin-coated onto this material layer prior to lithographic printing. The lithographic printing step is usually performed using an imaging tool, which has a high intensity light source, a relay lens, a reticle stage, an imaging lens and a high precision translation stage.

A reticle containing an IC pattern to be printed is illuminated by a high intensity, high-frequency energy source such as a light source, which may be a mercury arc lamp or a laser, at a specific wavelength that causes radiation-induced changes in the resist. The light passing through the reticle is imaged by the lens onto the resist layer on the wafer. In one lithographic process in which a stepper is used, after each exposure, the wafer is stepped by a translation stage to the next site for subsequent exposure. The wafer is positioned on the translation stage. This exposure step essentially generates a latent image of the circuit pattern in the resist, similar to the exposure of a photographic film in conventional photography, hence the term photolithography. The exposed resist can then be developed to produce a patterned resist layer, which can be used as a mask in a subsequent processing step, which, for example, transfers this pattern onto the underlying material layer. While the process is described in terms of a stepper, it will be recognized that a scanning process, whole wafer printer, or FPD printer uses the same general equipment, and that the invention to be described herein is adaptable to each of these processes.

In general, each of the photolithography processes exposes a plurality of die on the wafer surface. This is accomplished by having a mask or reticle on which a plurality of separate patterns are formed. The focused radiation source which may be in the form described above, including an ultraviolet light source, then images the patterns onto the wafer at precise locations. The equipment carries the light source and exposes the IC pattern across the wafer in a predetermined time dependent manner. The stepper moves laterally, for example, from left to right, in “steps” across the width of the wafer to expose a predetermined number of die in one or more rows and columns of die at each step and then steps to a new position to repeat the process and expose another group of rows and columns of dies. At each step, a finite number of die are exposed to create one or more circuit features. The number of die patterns that may be duplicated on a reticle and which will define the number of die that can be exposed at each exposure position of the stepper is generally related to the size of each die and can vary from one to thirty or more. However, there is a practical limit to the number of devices that can be exposed at any step due to limitations in the depth of focus of the imaging radiation source. More particularly, a point source of radiation will have a focal plane in the shape of a portion of a sphere when projected through a simple lens. However, the wafer on which the reticle image is being focused is typically flat. The larger the area exposed at any step, the more likely there will be one or more die at the edge of the area of exposure that will not be in the best focus. As features of die become smaller, the depth of focus becomes smaller therein exacerbating the focus problem. Lack of focus results in poor line definition that can result in poor device performance and/or failure of the device created on the wafer. A more detailed description of such a lithographic process may be obtained from U.S. Pat. No. 6,218,077, which describes the process in terms of a scanning system rather than a stepper.

The clarity, or definition, of the IC pattern which is projected from the reticle is a function of the depth of focus at the wafer surface. As with any lens system, the focal depth becomes decreasingly smaller with increased resolution, i.e., as the dimensions of the focused features on the wafer become smaller, the focal depth decreases proportionately. Accordingly, in order to maintain focus over a realistic area of the wafer for each exposure, the area must be reduced thereby reducing the number of die that can be exposed at any time. Efforts to overcome this area limitation have typically been directed at lens solutions to flatten the focal plane at the wafer surface. These optical solutions generally have resulted in the focal plane either curving upward or downward at the corners of a rectangular exposure area. While it may be appreciated that the usefulness of the image that is projected through the mask is largely a function of the optics as provided by the stepper, the ability to obtain the projection of that image across a focal plane that provides uniform exposure onto the wafer is critical in order to maximize the efficiency of the manufacturing process.

### BRIEF DESCRIPTION OF THE DRAWINGS

FIG. 1 is a simplified block diagram of a conventional photolithographic system for imaging of an integrated circuit on a wafer;

FIG. 2 is a diagram of the projection of a focal plane provided by the photolithographic system of FIG. 1; and

FIG. 3 is a simplified block diagram illustrating an apparatus and method for improved focus control in a photolithographic process such as would be carried out by the system of FIG. 1.

### DETAILED DESCRIPTION OF THE INVENTION

It has been observed that often there occurs some degree of difficulty in obtaining a full and proper exposure of the wafer, and particularly at the edges thereof, in the manufacture of integrated circuits (ICs). This difficulty generally stems from an inability to obtain a necessary alignment of the focal plane, as provided by a projection of light from an imaging device, such as a stepper or scanner, and the wafer surface. When such alignment is achieved, it is likely that a full exposure will result.

In achieving such alignment, various methods have been used. Such methods have included the aligning of marks placed on each of the wafer and the mask, and also tilting of the wafer relative to the stepper. More importantly, efforts to achieve focus across the area of exposure have relied on optical solutions, i.e., adding more and more lenses (sometimes as many as 20 different lenses), in an effort to flatten the exposure plane to match the wafers flat surface. Notwithstanding each of these exemplary attempts concerning alignment, further advancements are needed to obtain a proper exposure across a large area of the wafer.

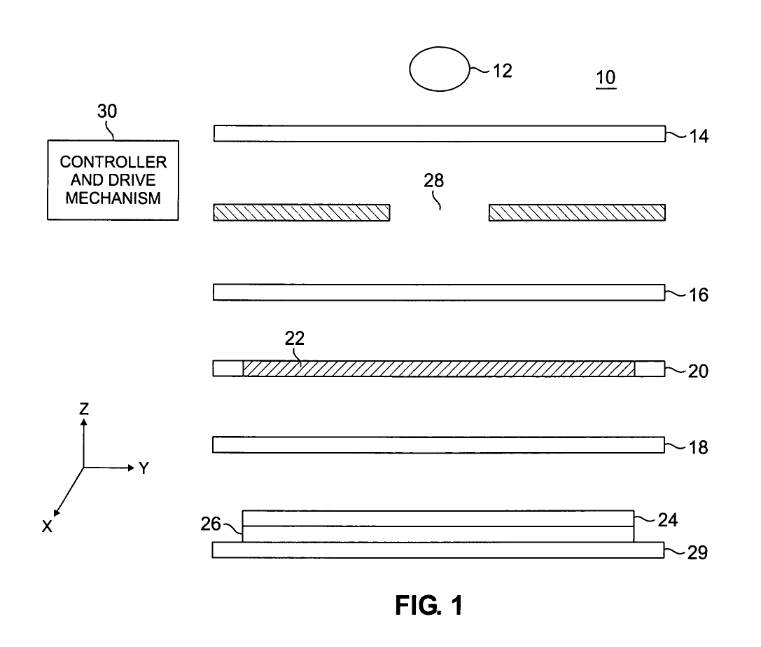

The issue of alignment, and its relation to obtaining proper exposure across a wafer surface, is best understood with reference to the FIGURES, wherein like reference numerals refer to like elements throughout. Referring to FIG. 1, a schematic diagram of an exemplary scanning system 10 is shown. The scanning system 10 includes a high intensity light or energy source 12, a condenser lens 14, a relay lens 16, an imaging lens 18, and a reticle translation stage 20 including a reticle 22. The resist 24 on the wafer 26 is exposed to the energy source 12 through a slit 28 which limits the area of the resist exposed by the energy source 12 through the reticle 20.

During the exposure operation, both the reticle 22 and the wafer 26 are stationary when the resist 24 is exposed to the energy source 12 in a stepper system. For a discussion of scanning system operation, reference may be had to the aforementioned U.S. Pat. No. 6,218,077. The reticle translation stage 20 moves the reticle 22 in one or more directions and a wafer translation stage 29 moves the wafer 26 in one or more directions. For example, the reticle translation stage 20 and the wafer translation stage 29 may respectively move the reticle 22 and the wafer 26 along parallel to planes. Typically, the reticle translation stage 20 is moved relative to the wafer translation stage 28 in a straight line (the scanning direction) in a plane parallel to the major surface of the wafer, referred to herein as an X-Y plane.

The reticle translation stage 20, sometimes referred to as a stepper, is operated by a control apparatus 30, which also controls the position of the wafer translation stage 29. The pattern imaged through the lenses 14, 16 and 18 is received upon the energy sensitive photoresist (PR) 24 disposed on the wafer creating a change in the characteristics of the PR so as to transfer the patterns from the reticle to the PR. As will be understood by one skilled in the art, the stepper 10 will, in a predetermined time dependent manner, image all of the wafer 26 by stepping through an imaginary grid above the wafer surface to expose a plurality of dies on the wafer. The distance between the imaging lens 18 and the surface of the wafer 26 may be adjusted in a z-direction (orthogonal to the X-Y plane) to a desired focal plane by tilting or otherwise moving the wafer translation stage 29. Movement of the reticle translation stage 20, the wafer translation stage 29, and other components is implemented by the controller and drive mechanism 30. An exemplary scanning system of the type described in FIG. 1 is the model S203 or S202 produced by Nikon Inc.

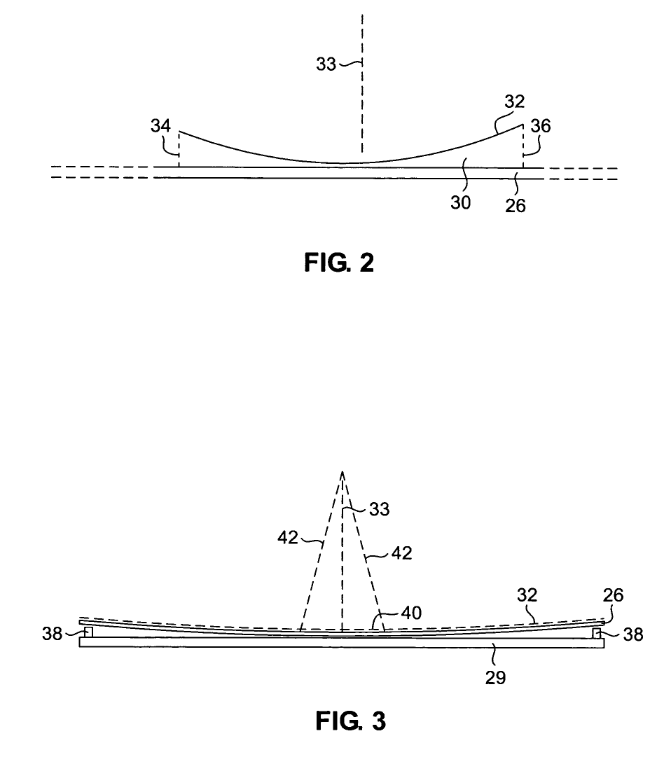

In looking to FIG. 2, there is provided an illustration of a focal plane 32 projected onto a surface 30 of the wafer 26. For simplicity, a reference to the wafer 26 or the surface 30 of wafer 26 as used hereinafter is intended to mean a major surface of the wafer which may be that of the substrate or any other layer of material on the substrate which is deposited and thereafter coated with PR for the purpose of defining features to be created on the wafer and in the dies formed on the wafer. As may be seen therein, the focal plane 32 created by a simple conventional lens bows and is distorted relative to the surface 30 of the wafer 26. While appearing simply as an arc in the cross-sectional view of FIG. 2, it will be appreciated that the area of focus is a three-dimensional bowl shaped area centered about a radius line 33 extending from the light source 12 through a center of slit 28. This distortion is emphasized at the edges 34 of the region of exposure at any one stepped position of the reticle or wafer. Accordingly, it may be appreciated that a patterned image projected by the scanning system 10 may provide for an uneven exposure at those edges 34 given the depth of focus of the source energy at the wafer surface. As such, exposure of the PR on the wafer surface 30, and thus the formation of the mask pattern in the PR may be non-uniform. Such non-uniformity may result in defects in some of the IC's formed on the wafer. The optical solution adds numerous lenses to flatten this “bowl” but typically does not correct for all portions of an area of exposure. Quite often, the corners of a rectangular exposure area are still not fully focused.

Referring to FIG. 3, it may be seen that it is contemplated that peripheral portions such as the radially outer edge 36 of the wafer 26 are bent so as to provide a concave curvature of the wafer 24. By way of example, bending of the wafer 26 may be achieved by elevating the edge 36 of the wafer, i.e., by positioning one or more concentric rings 38 as shown in FIG. 3 (viewed in cross-section), within the carrier 26. Vacuum seating of the wafer 26 within the carrier 29 conforms the wafer to the desired curvature. When providing such curvature, the contour of the wafer 26 over the exposed area within the bounds defined by phantom lines 42 generally conforms to the focal plane 32 projected through the mask 22, so that the curvature of the wafer 26 more closely matches the curvature of the focal plane. Accordingly, exposure of the wafer 26 at each position of the lithography apparatus will be more uniform over the exposure area. However, it will be recognized that the wafer curvature is idealized only at the wafer center. In order to produce similar results throughout the wafer surface, it is desirable to tilt the wafer or stepper relative to the z-axis so that the center of the area of exposure 40 on the wafer surface is normal to a centerline 33 from the light source through the center of the reticule and slit 28. Since it is common to provide some tilting of the wafer surface during conventional exposure processes, it is only necessary to revise the tilting process to cause the wafer to be tilted at different angles at each stepper position so as to align the center of the area of exposure with the reticle. By so doing, the entire area of exposure can be aligned with the accurately shaped focal plane of the stepper and reticle. The tilting of the wafer is implemented in a manner to maintain the spacing from the reticle to the wafer at the focal distance. It is noted that the focal plane need not match the wafer shape perfectly but only such that the area of exposure is within the focal depth defined by the focus optics of the stepper or scanner. Thus, the wafer curvature may be generally the same as the curvature of the focal plane.

While the majority of systems create a focal plane that is best fit by a concave wafer surface, as noted above, some optical solutions have resulted in a convex focal plane at the corners of the rectangular area of exposure through the mask or reticle. In such situations, the wafer can be distorted into a convex configuration by elevating the center of the wafer rather than the edge. The same approach of tilting could then be used to align the center of the area of exposure with the centerline through the reticle. In either the convex or concave solutions described above, the wafer can be distorted into the desired configuration by positioning a mechanical device under the wafer or by creating a shaped wafer carrier. The wafer can be held in the carrier using conventional techniques such as the aforementioned vacuum system.

It is to be understood that the optics, and particularly the lens through which the mask pattern is projected, will be suited to accomplish the conformance of the focal plane to the wafer surface as described herein, i.e., the optical system may have fewer lenses so that the focal plane conforms to the shape of FIG. 2.

Thus, there is provided a method for manufacturing an IC using photolithography in which greater conformity is achieved between curvature on the wafer surface and the focal plane when patterning multiple integrated circuits onto the wafer.

While various embodiments of the present invention have been shown and described herein, such embodiments are provided by way of example only. Numerous variations, changes and substitutions may be made without departing from the invention herein. Accordingly, the invention is limited only by the scope of the appended claims.

We claim:

1. A method of manufacturing an integrated circuit, the method comprising:
a) positioning a major surface of a wafer to receive high frequency energy defining a focal plane having an associated curvature and depth of focus; and
b) conforming curvature of the wafer surface to generally match the focal plane/curvature.

2. The method as recited in claim 1, further comprising: aligning the wafer such that a center of an area of exposure to the energy source is normal to a radius line extending from the energy source.

3. The method as recited in claim 2 wherein the step of aligning comprises tilting of the wafer relative to the energy source.

4. The method as recited in claim 1, wherein: conforming the wafer comprises providing a concave curvature to the wafer.

5. The method as recited in claim 1, wherein: conforming the wafer comprises providing a convex curvature to the wafer.

6. A method of manufacturing an integrated circuit, the method comprising:
a) exposing an area of a wafer to an energy source defining a focal plane with which a depth of focus is associated; and
b) bending the wafer into conformance with the focal plane so as to provide a curvature of the wafer at the area of exposure corresponding to that of the focal plane in order to obtain substantially uniform exposure of the area of the wafer.

7. The method as recited in claim 6, further comprising: locating the wafer within a carrier at a predetermined height relative thereto, and adjusting the height of the wafer therein to provide continuing correspondence with the focal plane at a center of the area of exposure; and
tilting the wafer so as to align the area of exposure with the focal plane.
